(19) United States
(12) Patent Application Publication
(10) Pub. No.: US 2015/0171186 A1
(43) Pub. Date: Jun. 18, 2015

(54) SEMICONDUCTOR DEVICE MANUFACTURING METHOD

(71) Applicants: Haizhou Yin, Poughkeepsie, NY (US); Huilong Zhu, Poughkeepsie, NY (US)

(72) Inventors: Haizhou Yin, Poughkeepsie, NY (US); Huilong Zhu, Poughkeepsie, NY (US)

(73) Assignee: Institute of Microelectronics, Chinese Academy of Sciences, Beijing (CN)

(21) Appl. No.: 14/413,697

(22) PCT Filed: Jul. 31, 2012
(86) PCT No.: PCT/CN2012/079454

§ 371 Date: Jan. 8, 2015

(30) Foreign Application Priority Data
Jul. 11, 2012 (CN) 201210239480.8

(51) Int. Cl. H01L 29/66; H01L 21/311; H01L 21/3105; H01L 29/45; H01L 21/3205; H01L 29/417; H01L 21/02

(52) U.S. Cl. CPC H01L 29/6659; H01L 29/665; H01L 29/66545; H01L 29/66636; H01L 29/6656; H01L 29/41783; H01L 21/31111; H01L 21/31144; H01L 21/02532; H01L 21/0257; H01L 29/45; H01L 21/32053; H01L 21/31053

(57) ABSTRACT

The present application discloses a method for manufacturing a semiconductor device, comprising: forming a gate stack structure and gate sidewall spacers on the substrate, and forming a source region and a drain region on the substrate on opposite sides of the gate stack structure and the gate sidewall spacers, respectively; selectively forming a block layer in the drain region, wherein the block layer covers the drain region and exposes the source region; epitaxially forming an raised source region in the exposed source region; removing the block layer. According to the semiconductor device manufacturing method in the present disclosure, by selectively forming an raised source region in the source region side to form an asymmetric device structure, the parasitic resistance on the source region side and the parasitic capacitance on the drain region side are pertinently reduced and the device performance is effectively improved.

### CROSS-REFERENCE TO RELATED APPLICATION

This application claims priority to the Chinese Patent Application No. 201210239480.8, filed on Jul. 11, 2012, entitled “semiconductor device manufacturing method”, which is incorporated herein by reference in its entirety.

### TECHNICAL FIELD

The present disclosure relates to semiconductor integrated circuit manufacturing field, and specifically, to a semiconductor device manufacturing method, and in particular, to the manufacturing method of a MOSFET with asymmetric S/D structure.

### BACKGROUND

With the continuous development of integrated circuit process, and in particular, with the continuous proportional scaling-down of the device size, the parasitic effects in conventional MOSFET become more and more prominent. For example, the S/D parasitic resistance in a long channel is much less than the channel region resistance and can be omitted, however, with the proportional scaling-down of the device, the intrinsic resistance of the channel region decreases, the S/D region resistance, in particular, the contact resistance, increases rapidly with the size decreasing, and the equivalent operating voltage decreases. In additional, there are parasitic capacitances between the source/drain and the gate, including parasitic capacitances caused by electric field lines from the gate penetrating through the sidewall spacers and the interlayer dielectric and entering into the source/drain regions due to edge electronic field effect. This will cause deterioration of the device response speed and reducing the device high frequency performance. Therefore, it is required to reduce the above parasitic resistance and parasitic capacitance.

In current technology, the methods used to reduce the parasitic effects comprise forming a metal silicide in/on the S/D region, or simultaneously reducing the source and drain parasitic resistance by raised source and drain, and reducing the parasitic capacitance by precise control of the gate height, gate sidewall spacer lines, and composition of gate sidewall spacers.

However, the above methods use the same process on both of the source region and drain region, i.e., the formed device structure is symmetric. Furthermore, the raised S/D will increase the edge parasitic capacitance since the distances of the electric field lines from the gate entering into S/D through the sidewall spacers decreases. In fact, the cover capacitance between gate and drain is the Miller capacitance between the gate as an input terminal and the drain as an output terminal, and the equivalent capacitance from the input terminal in an inverting amplifier will amplify 1+K times (where K is the voltage magnification of the amplifier) due to the magnification effect of the amplifier. Therefore, the parasitic capacitance of the drain side has greater influence than that of the source side due to the Miller effect. In addition, when the device is on, the source parasitic resistance cause changes in source voltage and further in gate-source voltage, which lowers the gate-source voltage in NMOS and lowers the absolute value of the gate-source voltage in PMOS. This will increase the channel resistance, reduce the amount of channel charge, and thus reduce the driving current and affect the device performance. Relatively, the drain parasitic resistance to drain voltage will not affect the gate-source voltage and have less effect on device performance. So overall, the influence of the parasitic resistance of the source side to device performance is greater than that of the drain side.

Therefore, in current technology the MOSFET with symmetric structure does not take into account the above difference in parasitic effects between source region and drain region, and further improvement of the device performance is restricted.

### SUMMARY OF THE DISCLOSURE

The purpose of the present disclosure is to provide a semiconductor device manufacturing method, and in particular, a manufacturing method of a MOSFET with asymmetric S/D structure to pertinently reduce the source parasitic resistance and the drain parasitic capacitance.

The purpose of the present disclosure is realized by providing a semiconductor device manufacturing method, comprising: forming a gate stack structure and gate sidewall spacers on the substrate, and forming a source region and a drain region on the substrate on opposite sides of the gate stack structure and the gate sidewall spacers, respectively; selectively forming a block layer in the drain region, wherein the block layer covers the drain region and exposes the source region; epitaxially forming an raised source region in the exposed source region; and removing the block layer.

The materials for the block layer differ from the materials for the substrate.

The step for selectively forming the block layer in the drain region further comprises: forming a block material layer on the entire device; forming a photoresist pattern on the block material layer to cover the block material layer on the drain region and to expose the block material layer on the source region; etching the block material layer on the exposed source region and retaining part of the block material layer on the drain region to form the block layer; and removing the photoresist pattern.

The raised source region comprises at least one material selected from a group consisting of Si, SiGe, and Si:C.

The raised source region has the same type in conductivity as the source region by in-situ doping when forming the raised source region or by impurity implantation after the raised source region is formed.

It also comprises after removing the block layer: forming a metal silicide on the drain region and the raised source region; forming an interlayer dielectric layer on the entire device; etching the interlayer dielectric layer until the metal silicide is exposed to form an S/D contact hole; and forming an S/D contact plug by deposition in the S/D contact hole.

The gate stack structure is a dummy gate stack structure, comprising a pad oxide layer of silicon oxide and a dummy gate filling layer of polycrystalline silicon, amorphous silicon, or silicon oxide.

It also comprises, after the interlayer dielectric is formed and before the interlayer dielectric is etched: planarizing the interlayer dielectric layer and the dummy gate stack structure until the gate filling layer is exposed; removing the gate filling layer to form a gate gap; and forming a work function adjusting layer and a resistance adjusting layer in the gate gap.

The source region and/or drain region comprise a lightly doped extension region and a heavily doped region.

The source region and the drain region are symmetric to each other.

According to the semiconductor device manufacturing method in the present disclosure, by selectively forming an raised source region in the source region side to form an asymmetric device structure, the parasitic resistance on the source region side and the parasitic capacitance on the drain region side are pertinently reduced and the device performance is effectively improved.

### BRIEF DESCRIPTION OF THE DRAWINGS

The technical solutions of the present disclosure will be described in more details below with reference to the accompanying drawings, wherein:

FIG. 1 is a schematic flow chart showing the method for manufacturing a semiconductor device according to the present disclosure; and

FIGS. 2-8 are schematic cross-sectional views of the various stages for manufacturing the semiconductor device according to the present disclosure.

### DETAILED DESCRIPTION

Exemplary embodiments of the present disclosure will be described in more details below with reference to the accompanying drawings, to illustrate the features and effects of the technical solutions of the present disclosure. It should be noted that similar reference numerals denote similar member in the drawings. The terms “first”, “second”, “above”, “below”, “thick”, “thin”, etc. can be used to describe all device structures. The description does not imply the space, order, or hierarchical relationship between the descriptive device members or process stages unless otherwise indicated.

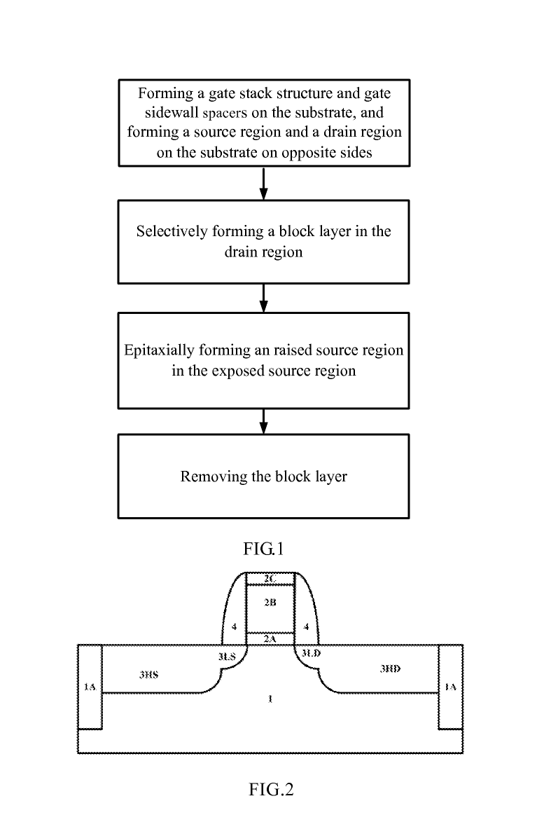

Referring to FIGS. 1 and 2, a gate stack structure and gate sidewall spacers are formed on the substrate, and a source region and a drain region are formed on the substrate on both sides of the gate stack structure and the gate sidewall spacers, respectively.

The substrate 1 is provided, the materials of which can be (bulk) silicon (for example, single crystal silicon wafer), SOI, GeOI (Ge on insulator), or other compound semiconductor, such as GaAs, SiGe, GeSn, InP, InSb, GaN, etc. Preferably, bulk silicon or SOI are chosen for the substrate 1 to be compatible with the CMOS process. Preferably, the substrate 1 is etched to form a shallow trench and insulator materials such as silicon oxide are deposited and filled in the trench to form a shallow trench insolation (STI) 1A, where the substrate 1 surrounded by STI 1A constitutes the device active region.

A gate insulation layer 2A, a gate filling layer 2B, and a preferred gate cover layer 2C are formed by successive deposition and subsequent etching in the active region using conventional deposition methods such as LPCVD, PECVD, HDPCVD, MOCVD, MBE, ALD, evaporation, sputtering, etc. When the back gate process is used in the gate stack structure, i.e., used as a dummy gate stack structure, the dummy gate insulation layer 2A is a pad oxide layer of silicon oxide and the dummy gate filling layer 2B is poly-crystalline silicon, amorphous silicon, or even silicon oxide. In the subsequent process, a gate gap is formed by etching to remove the dummy gate stack structure and a gate insulation layer of high k materials and a gate filling layer of metal materials are filled successively in the gate gap. The gate insulation layer 2A is made of high k materials comprising but not limited to nitrides (such as SiN, AlN, TiN), metal oxides (mainly oxides of the sub-group and lanthanide metal elements, such as Al₂O₃, Ta₂O₅, TiO₂, ZnO, ZrO₂, HfO₂, CeO₂, Y₂O₃, La₂O₃), perovskite oxides (such as PbZrₓTi₁₋ₓO₃ (PZT), BaₓSr₁₋ₓTiO₃ (BST)); the gate filling layer 2B is metals, metal nitrides, and combinations thereof, where the metals comprising Al, Ti, Cu, Mo, W, Ta are used as the gate filling layer (resistance adjusting layer), and the metal nitrides comprising TiN, TaN are used as work function adjusting layer; the metal cover layer 2C is silicon nitride, using as the hard mask in gate etching. The gate insulation layer surrounds the bottom and side (not shown) of the gate filling layer. Note that although the exemplary embodiment in the present disclosure is targeted to a back gate process, i.e., the gate stack structure in FIG. 2 is a dummy gate stack structure, the front gate process can also be used in the present disclosure. The gate stack structure and the filling metal type in front gate process differ from that in back gate process, and will not be described in detail herein since the current mainstream process is back gate process.

Optionally, the first S/D implantation is executed to implant symmetrically with lower energy and dose impurities such as B, P, Ga, Al, N, and combinations thereof, on the substrate 1 on both sides of the gate stack structure 2 constituting of the gate insulation layer 2A, the gate filling layer 2B, and the gate cover layer 2C, to form a lightly doped source region 3LS and a lightly doped drain region 3LD (this lightly doped S/D region or S/D extension region constitutes LDD structure to suppress the hot electron effect). The implantation dose and energy can be set reasonably according to the junction depth and the requirement in conductivity type and impurity concentration. The implanted impurity can be activated by annealing.

Gate sidewall spacers 4 of materials comprising silicon nitride, silicon oxide, silicon oxynitride, diamond-like amorphous carbon (DLC), and combinations thereof are formed by etching after deposition on both sides of the gate stack structure 2 constituting of the gate insulation layer 2A, the gate filling layer 2B, and the gate cover layer 2C.

Optionally, the second S/D implantation is executed to implant symmetrically with higher energy and dose impurities of the same conductivity type to form a heavily doped source region 3HS and a heavily doped drain region 3HD on the substrate 1 on both sides of the gate sidewall spacers 4. Again the implanted impurities can be activated by annealing.

Referring to FIGS. 1 and 3-6, a block layer is selectively formed in the drain region to cover the drain region side and to expose the source region side.

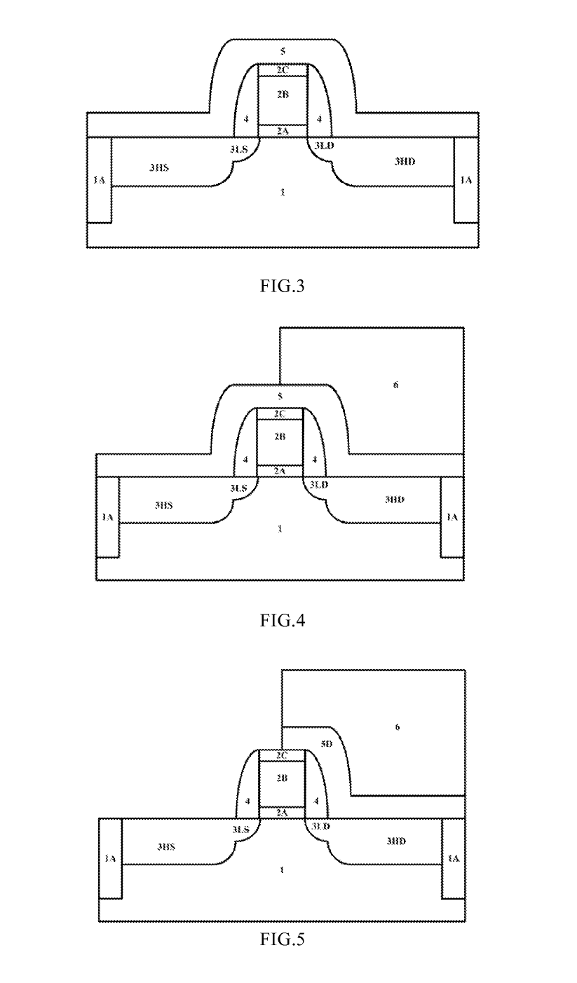

Referring to FIG. 3, a block material layer 5 is deposited on the entire device. The block material layer 5 is deposited on the STI 1A, the source region 3HS, the gate sidewall spacers 4, the gate cover layer 2C, and the drain region 3HD using conventional methods such as LPCVD, PECVD, HDPCVD, MBE, ALD, etc. The materials for the block material layer 5 comprise silicon oxide, silicon nitride, silicon oxynitride, and combinations thereof, either single layer or composite stack structure of these materials. In principle, the materials for the block layer can be any materials different from that for the source and drain regions. In order to ensure the gate sidewall spacers on source side and the gate cover layer (the etch stop layer) 2C are not etched, the materials for the block layer 5 should be different from those for the sidewall spacers 4 and the etch stop layer 2C. For example, when the substrate 1, the source region and the drain region are of silicon, and the sidewall spacers 4 and the cover layer 2C are of SiN, the block material layer 5 can be silicon oxide or silicon oxynitride. The block material layer 5 is used as the block material for the raised source region formed by subsequent epitaxy, the region covered by which cannot epitaxially grow the substrate/S/D region material. The depth of the block material layer 5 should be set according to the requirement in epitaxy process, such as 5˜30 nm.

Referring to FIG. 4, a mask pattern 6 is formed on the block material layer 5 to expose the source region side. A soft mask pattern of photoresist, for example, is spin-coated, spray-coated, or screen printed on the block material layer 5, and after exposure and development the photoresist pattern 6 is retained only on the drain region side and the photoresist on the source region side is removed. The (photoresist) mask pattern 6 can occupy strictly the entire drain region and one half of the gate stack structure by the boundary of the device central axis, as shown in FIG. 4, or take other forms as far as the source region side is exposed and the drain region side is covered, for example, the left boundary of the photoresist pattern 6 is located on the right of the left side of the left gate sidewall spacer 4 and on the left of the right side of the right gate sidewall spacer 4, and the right boundary of the photoresist pattern 6 is located on the right of the right side of the drain region 3HD.

Referring to FIG. 5, the exposed block material layer 5 is etched until the source region 3HS (and the gate sidewall spacers 4 and the gate cover layer 2C) is exposed. The etching method can be chosen reasonably according to the materials of the block material layer 5, either dry etching or wet etching. Dry etching comprises plasma etching, reactive ion etching etc., where the etching gas can be F-based gas (fluorocarbon-based gas, such as CF₄, CHF₃, CH₃F, CH₂F₂; NF₃; SF₆), Cl₂/HCl, Br₂/HBr, oxygen, noble gas (Ar, He), and combinations thereof. The corrosive liquid in wet etching can be HF, HF:NH₄F, H₂O₂, H₂SO₄, HNO₃, and combinations thereof. The etching can also be combinations of dry etching and wet etching, for example, dry etching before wet etching, or using different dry etching combination, wet etching combination, or dry etching and wet etching combination for stacked block material layer 5. As described previously, since the materials for the block material layer 5 and the sidewall spacers 4 and the etch stop layer 2C are different, the sidewall spacers 4 and the etch stop layer 2C will not be etched during the etch process.

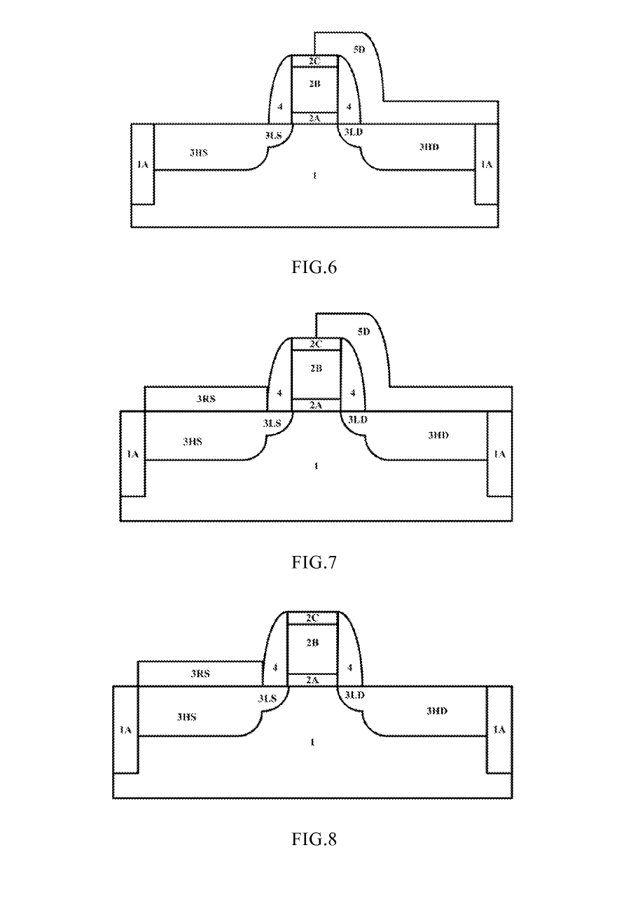

Referring to FIG. 6, the mask pattern 6 is removed and the block layer 5D is retained on the drain region 3HD side. The methods for removing the photoresist can be dissolution in organic solvent, oxidation in inorganic solvent, or ashing with oxygen plasma, etc.

Referring to FIGS. 1-7, a raised source region is epitaxially grown on the source region. The raised source 3RS is epitaxially grown on the exposed source region 3HS using methods such as MBE, ALD, MOCVD, etc. Since the materials for STI 1A, gate sidewall spacers 4, gate cover layer 2C and block layer 5D differ from materials for substrate 1/source region 3HS, only the source region 3HS is epitaxially grown, and thus this is called selective epitaxy. The materials for the raised source region 3RS comprise Si, SiGe, Si:C, and combinations thereof. Preferably, SiGe and Si:C are chosen to apply stress to the channel region to improve the carrier mobility in the channel region. Preferably, at the same time during epitaxial growth, in-situ doping can be applied to make the enhance region 3RS to be the same conductivity type as the source region 3HS. Optionally, after epitaxial growth of the raised source region 3RS, doping ion implantation can be executed again and subsequently the impurities can be activated by annealing to make the raised source region 3RS to be the same conductivity type as the source region 3HS. At this moment, the raised drain region will not form on the drain region 3HD due to the block of the block layer 5D. Therefore, the electric field line in the gate 2B will not additionally penetrate into the raised drain region and cause the increase in parasitic capacitance, i.e., it reduces the parasitic capacitance on the drain region side by not forming the raised drain region. In addition, the raised source region 3RS on the source region side increases the source region area and the impurity concentration and reduces the parasitic resistance, and further improves the device performance.

Referring to FIGS. 1-8, the block layer 5D is removed. According to the materials for the block layer 5D, the remaining block layer 5D is removed using the same process as shown in FIG. 5. Next, the subsequent MOSFET manufacturing process (not shown) can be finished, including, for example, forming a metal silicide on the raised region 3RS and the drain region 3HD to further reduce the contact resistance, forming an interlayer dielectric layer (ILD) on the entire device, etching the ILD until the metal silicide is exposed to form an S/D contact hole, depositing metal/metal nitride in the S/D contact hole to form an S/D contact plug, etc. When the back gate process is used in the stack structure, after the interlayer dielectric is formed and before the interlayer dielectric is etched, it can also comprises: planarizing the interlayer dielectric layer and the dummy gate stack structure until the gate filling layer is exposed; removing the gate filling layer to form a gate gap; forming a work function adjusting layer and a resistance adjusting layer in the gate gap, wherein the metals for the work function adjusting layer and the resistance adjusting layer are described previously.

According to the semiconductor device manufacturing method in the present disclosure, by selectively forming an raised source region in the source region side to form an asymmetric device structure, the parasitic resistance on the source region side and the parasitic capacitance on the drain region side are pertinently reduced and the device performance is effectively improved.

Although the invention has been already illustrated according to the above one or more examples, it will be appreciated that numerous modifications and embodiments may be devised by the skilled in the art without deviating the scope of the invention. Furthermore, it may be devised from the teachings of the disclosure changes suitable for special situation or materials without deviating the scope of the invention. Therefore, objects of the disclosure are not limited to special examples for preferred embodiments, meanwhile structure of the device and manufacture method thereof cover all embodiments fall into the scope of the invention.

I/we claim:

1. A method for manufacturing a semiconductor device, comprising:
forming a gate stack structure and gate sidewall spacers on the substrate, and forming a source region and a drain region on the substrate on opposite sides of the gate stack structure and the gate sidewall spacers;
selectively forming a block layer in the drain region, wherein the block layer covers the drain region and exposes the source region;
epitaxially forming an raised source region in the exposed source region; and
removing the block layer.

2. The method for manufacturing the semiconductor device according to claim 1, wherein a material of the block layer differ from a material of the substrate.

3. The method for manufacturing the semiconductor device according to claim 1, wherein the step for selectively forming the block layer in the drain region further comprises:
forming a block material layer on the entire device;
forming a photoresist pattern on the block material layer to cover the block material layer on the drain region and to expose the block material layer on the source region;
etching the block material layer on the exposed source region and retaining part of the block material layer on the drain region to form the block layer; and
removing the photoresist pattern.

4. The method for manufacturing the semiconductor device according to claim 1, wherein the raised source region comprises at least one material selected from a group consisting of Si, SiGe, and Si:C.

5. The method for manufacturing the semiconductor device according to claim 1, wherein the enhanced source region has the same type in conductivity as the source region by in-situ doping when forming the enhanced source region or by impurity implantation after the enhanced source region is formed.

6. The method for manufacturing the semiconductor device according to claim 1, wherein, after removing the block layer, the method further comprises:
forming a metal silicide on the drain region and the raised source region;
forming an interlayer dielectric layer on the entire device;
etching the interlayer dielectric layer until the metal silicide is exposed to form an S/D contact hole; and
forming an S/D contact plug by deposition in the S/D contact hole.

7. The method for manufacturing the semiconductor device according to claim 6, wherein the gate stack structure is a dummy gate stack structure comprising a pad oxide layer of silicon oxide and a dummy gate filling layer of polycrystalline silicon, amorphous silicon, or silicon oxide.

8. The method for manufacturing the semiconductor device according to claim 7, wherein, after the interlayer dielectric is formed and before the interlayer dielectric layer is etched, the method further comprises:
planarizing the interlayer dielectric layer and the dummy gate stack structure until the dummy gate filling layer is exposed;
removing the dummy gate filling layer to form a gate gap; and
forming a work function adjusting layer and a resistance adjusting layer in the gate gap.

9. The method for manufacturing the semiconductor device according to claim 1, wherein the source region and/or the drain region comprise a lightly doped extension region and a heavily doped region.

10. The method for manufacturing the semiconductor device according to claim 1, wherein the source region and the drain region are symmetric to each other.
